(19) United States
(12) Patent Application Publication
(10) Pub. No.: US 2026/0058614 A1
(43) Pub. Date: Feb. 26, 2026

(54) LOW NOISE AMPLIFIER INCLUDING AN AIR BRIDGE

(71) Applicant: ELECTRONICS AND TELECOMMUNICATIONS RESEARCH INSTITUTE, Daejeon (KR)

(72) Inventors: Woojin CHANG, Daejeon (KR); Dong Min KANG, Daejeon (KR); Junhyung KIM, Daejeon (KR); Byoung-Gue MIN, Daejeon (KR); Jongyul PARK, Daejeon (KR); Gyejung LEE, Daejeon (KR); Jongmin LEE, Daejeon (KR); Junhyung JEONG, Daejeon (KR); Kyu Jun CHO, Daejeon (KR); Hong Gu JI, Daejeon (KR)

(73) Assignee: ELECTRONICS AND TELECOMMUNICATIONS RESEARCH INSTITUTE, Daejeon (KR)

(21) Appl. No.: 18/964,298

(22) Filed: Nov. 29, 2024

(30) Foreign Application Priority Data
Aug. 23, 2024 (KR) 10-2024-0113482

(51) Int. Cl. H03F 3/193; H03F 1/56

(52) U.S. Cl. CPC H03F 3/193; H03F 1/56; H03F 2200/294; H03F 2200/451

(57) ABSTRACT

Disclosed is a low noise amplifier which includes a low amplification circuit. The low noise amplification circuit includes a first source pattern that extends in a first direction, a first gate finger that is spaced apart from the first source pattern in a second direction perpendicular to the first direction, a second gate finger that is spaced apart from the first gate finger in the second direction, a second source pattern that is spaced apart from the second gate finger in the second direction, and an air bridge that makes contact with the first and second source patterns in a third direction perpendicular to a plane defined by the first and second directions and that is spaced apart from the first and second gate fingers in the first direction.

### CROSS-REFERENCE TO RELATED APPLICATIONS

This application claims priority under 35 U.S.C. §119 to Korean Patent Application No. 10-2024-0113482 filed on Aug. 23, 2024, in the Korean Intellectual Property Office, the disclosures of which are incorporated by reference herein in their entireties.

### BACKGROUND

Embodiments of the present disclosure described herein relate to a communication device, and more particularly, relate to a low noise amplifier including an air bridge.

A wireless communication device exchanges a radio frequency (RF) signal with another wireless communication device. The wireless communication device includes a transmitter and a receiver. The receiver includes a low noise amplifier (LNA). The low noise amplifier performs a low noise amplification operation of the RF signal.

The low noise amplifier includes transistors. The circuit structure of the transistors may affect the size of the low noise amplifier. The process structure of the transistors may affect the low noise amplification operation of the RF signal. A design of the low noise amplifier for minimizing the size of the low noise amplifier and reducing noise of the low noise amplification operation may be required.

### SUMMARY

Embodiments of the present disclosure provide a low noise amplifier including an air bridge.

According to an embodiment, a low noise amplifier includes a first matching circuit that generates an input signal, based on an input radio frequency signal, a low noise amplification circuit that generates an output signal, based on the input signal, and a second matching circuit that radiates an output radio frequency signal, based on the output signal. The low noise amplification circuit includes a first source pattern that extends in a first direction and has a first length in the first direction, a first gate finger that receives the input signal and that is spaced apart from the first source pattern in a second direction perpendicular to the first direction, the first gate finger having a second length shorter than the first length in the first direction, a drain pattern that generates the output signal and that is spaced apart from the first gate finger in the second direction, a second gate finger that receives the input signal and that is spaced apart from the drain pattern in the second direction, the second gate finger having the second length in the first direction, a second source pattern that is spaced apart from the second gate finger in the second direction and that has the first length in the first direction, and an air bridge that makes contact with the first and second source patterns in a third direction perpendicular to a plane defined by the first and second directions and that is spaced apart from the first and second gate fingers in the first direction.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a low noise amplifier according to an embodiment of the present disclosure.

FIG. 2 is a circuit diagram illustrating a general low noise amplifier.

FIG. 3 is a view illustrating a general low noise amplification circuit.

FIG. 4 is a view illustrating the general low noise amplification circuit.

FIG. 5 is a view illustrating the general low noise amplification circuit.

FIG. 6 is a view illustrating a low noise amplification circuit according to some embodiments of the present disclosure.

FIG. 7 is a view illustrating the low noise amplification circuit according to some embodiments of the present disclosure.

FIG. 8 is a view illustrating the low noise amplification circuit according to some embodiments of the present disclosure.

FIG. 9 is a view illustrating the low noise amplification circuit according to some embodiments of the present disclosure.

FIG. 10 is a graph depicting an improvement in the amplification gain of the low noise amplifier according to some embodiments of the present disclosure.

FIG. 11 is a graph depicting an improvement in the noise factor of the low noise amplifier according to some embodiments of the present disclosure.

FIG. 12 is a circuit diagram illustrating a low noise amplification circuit having more than two source patterns according to some embodiments of the present disclosure.

FIG. 13 is a view illustrating a general low noise amplification circuit having more than two source patterns.

FIG. 14 is a view illustrating a low noise amplification circuit having more than two source patterns according to some embodiments of the present disclosure.

### DETAILED DESCRIPTION

Hereinafter, embodiments of the present disclosure will be described clearly and in detail to such an extent that those skilled in the art easily implement the present disclosure.

The terms “unit” and “module” used herein or function blocks illustrated in the drawings may be implemented in the form of a software component, a hardware component, or a combination thereof. Hereinafter, in order to clearly explain the spirit and scope of the present disclosure, detailed descriptions of overlapping components will be omitted.

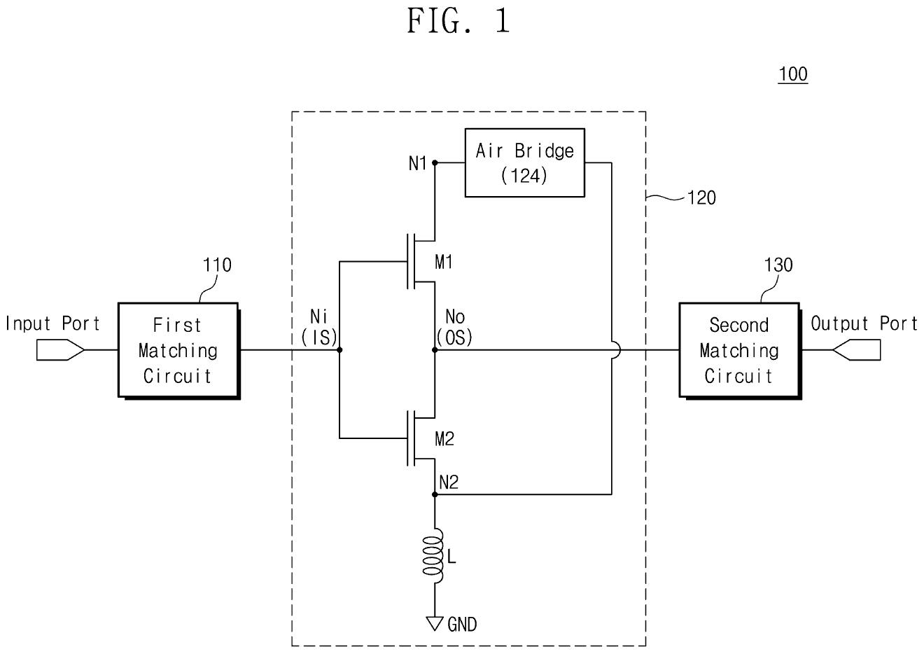

FIG. 1 is a block diagram illustrating a low noise amplifier according to an embodiment of the present disclosure. Referring to FIG. 1, the low noise amplifier 100 will be described. The low noise amplifier 100 may be used in a wireless communication device. The wireless communication device may exchange a radio frequency (RF) signal with another wireless communication device. For example, the wireless communication device may include a transmitter and a receiver. The receiver may include the low noise amplifier 100. The low noise amplifier 100 may perform a low noise amplification operation of the RF signal.

The lower noise amplifier 100 may include an input port, an output port, a first matching circuit 110, a low noise amplification circuit 120, and a second matching circuit 130.

The first matching circuit 110 may receive an RF input signal RFi through the input port. The first matching circuit 110 may generate an input signal IS, based on impedance matching of the RF input signal RFi. The first matching circuit 110 may provide the input signal IS to the low noise amplification circuit 120.

The low noise amplification circuit 120 may include a first transistor M1, a second transistor M2, an air bridge 124, and an inductor L. The first transistor M1 may be connected between a first node N1 and an output node No and may operate in response to the input signal IS. The second transistor M2 may be connected between the output node No and a second node N2 and may operate in response to the input signal IS. The air bridge 124 may connect the first node N1 of the first transistor M1 and the second node N2 of the second transistor M2. The inductor L may connect the air bridge 124 and a ground node GND.

The air bridge 124 may be an element that connects nodes or patterns physically spaced apart from each other. The air bridge 124 may short-circuit the first node N1 and the second node N2 of the low noise amplifier 100. The first node N1 and the second node N2 correspond to the source of the first transistor M1 and the source of the second transistor M2, respectively. By sharing the inductor L, which is an inductive element, the size of the low noise amplifier 100 may be reduced.

The low noise amplification circuit 120 may receive the input signal IS from the first matching circuit 110 through an input node Ni. The input node Ni may be connected with the gate pattern of the first transistor M1 and the gate pattern of the second transistor M2. The low noise amplification circuit 120 may generate an output signal OS at the output node No. The low noise amplification circuit 120 may provide the output signal OS to the second matching circuit 130 through the output node No. The output node No may be connected with the drain pattern of the first transistor M1 and the drain pattern of the second transistor M2.

The second matching circuit 130 may provide an RF output signal RFo to the output port. The second matching circuit 130 may generate the RF output signal RFo, based on impedance matching of the output signal OS.

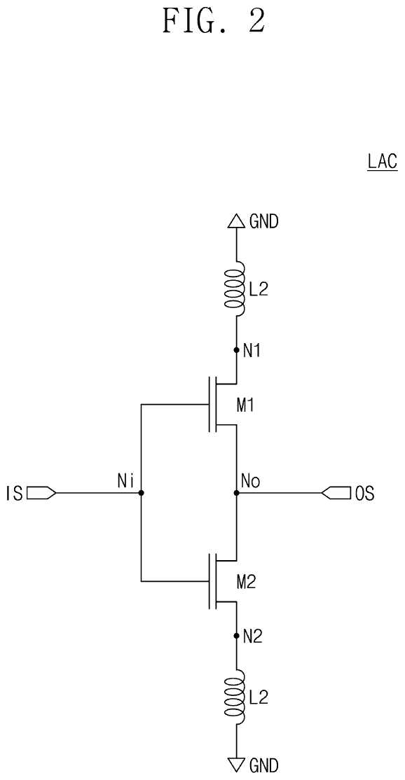

FIG. 2 is a circuit diagram illustrating a general low noise amplifier. Referring to FIG. 2, a circuit diagram of a general low noise amplification circuit LAC is illustrated. The general low noise amplification circuit LAC may correspond to the low noise amplification circuit 120 of FIG. 1 according to an embodiment of the present disclosure. The general low noise amplification circuit LAC is described only for a better understanding of the low noise amplification circuit 120 of the present disclosure, and the general low noise amplification circuit LAC may include other components that do not constitute a prior art.

The general low noise amplification circuit LAC may receive an input signal IS from the first matching circuit 110 through an input node Ni. The general low noise amplification circuit LAC may generate an output signal OS at an output node No, based on a low noise amplification operation of the input signal IS.

The general low noise amplification circuit LAC may include a first transistor M1, a second transistor M2, a first inductor L1, and a second inductor L2. The first inductor L1 may be connected between a ground node GND and a first node N1. The first transistor M1 may be connected between the first node N1 and the output node No and may operate in response to the input signal IS. The second transistor M2 may be connected between the output node No and a second node N2 and may operate in response to the input signal IS. The second inductor L2 may be connected between the second node N2 and a ground node GND. Since the first inductor L1 and the second inductor L2 operate in parallel in the circuit connection, the inductance values of the first inductor L1 and the second inductor L2 may be twice the inductance value of the inductor L of FIG. 1. Accordingly, the circuit area of the general low noise amplification circuit LAC that includes the first inductor L1 and the second inductor L2 may be greater than the area of the low noise amplification circuit 120 of FIG. 1 that includes the inductor L.

The input signal IS received by the general low noise amplification circuit LAC may be transferred to the input node Ni of the general low noise amplification circuit LAC. The gate pattern of the first transistor M1 or the gate pattern of the second transistor M2 may be connected to the input node Ni. The output signal OS provided by the general low noise amplification circuit LAC may be connected to the output node No of the general low noise amplification circuit LAC. The drain pattern of the first transistor M1 or the drain pattern of the second transistor M2 may be connected to the output node No.

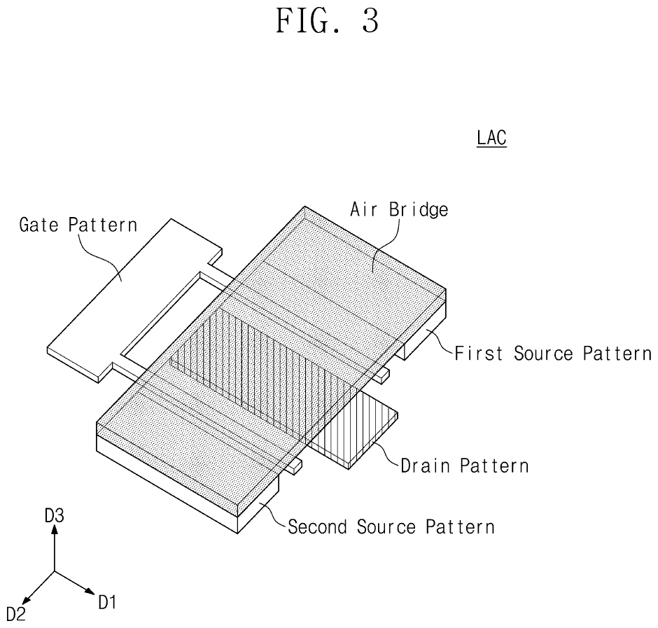

FIG. 3 is a view illustrating the general low noise amplification circuit LAC. Referring to FIGS. 2 and 3, a process drawing of the general low noise amplification circuit LAC is illustrated. Hereinafter, for convenience of description, a first direction D1, a second direction D2, and a third direction D3 are mentioned. The first direction D1 may be parallel to a semiconductor substrate on which the general low noise amplification circuit LAC is implemented. The second direction D2 may be perpendicular to the first direction D1. The third direction D3 may be perpendicular to a plane defined by the first and second directions D1 and D2.

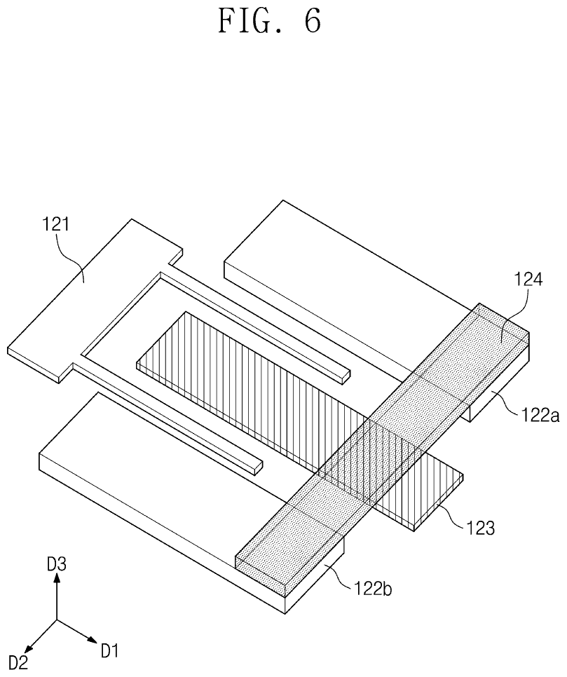

The general low noise amplification circuit LAC may include a first source pattern, a second source pattern, a gate pattern, a drain pattern, and an air bridge. The gate pattern may include a gate body, a first gate finger, and a second gate finger. The general first gate finger may be located between the first source pattern and the drain pattern in the second direction D2 and may overlap the air bridge in the third direction D3. The general second gate finger may be located between the second source pattern and the drain pattern in the second direction D2 and may overlap the air bridge in the third direction D3. Gate fingers of the present disclosure will be described below with reference to FIG. 6. The gate body may refer to a portion of the gate pattern excluding the first and second gate fingers.

The first source pattern, the first gate finger, and the drain pattern may correspond to the first transistor M1. The second source pattern, the second gate finger, and the drain pattern may correspond to the second transistor M2.

The first source pattern may be connected to the first node N1. The second source pattern may be connected to the second node N2. The gate pattern may be connected to the input node Ni. The drain pattern may be connected to the output node No.

The first source pattern may extend in the first direction D1.

The gate body may be connected with the first gate finger and the second gate finger. The first gate finger may be spaced apart from the first source pattern in the second direction D2.

The drain pattern may be spaced apart from the first gate finger in the second direction D2. The drain pattern may generate the output signal OS.

The second gate finger may be spaced apart from the drain pattern in the second direction D2.

The second source pattern may be spaced apart from the second gate finger in the second direction D2.

The first source pattern, the first gate finger, the drain pattern, the second gate finger, and the second source pattern may have the same length in the first direction D1.

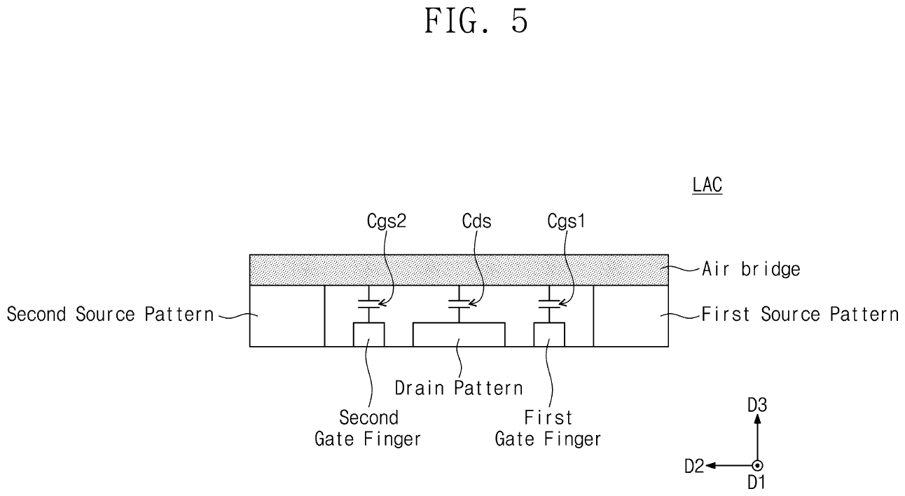

The air bridge may make contact with the first source pattern and the second source pattern in the third direction D3. The air bridge may overlap a portion of the first gate finger and a portion of the second gate finger in the third direction D3. The overlapping portions may function as a parasitic capacitor. The parasitic capacitor may increase communication noise. More detailed description thereabout will be given below with reference to FIG. 5.

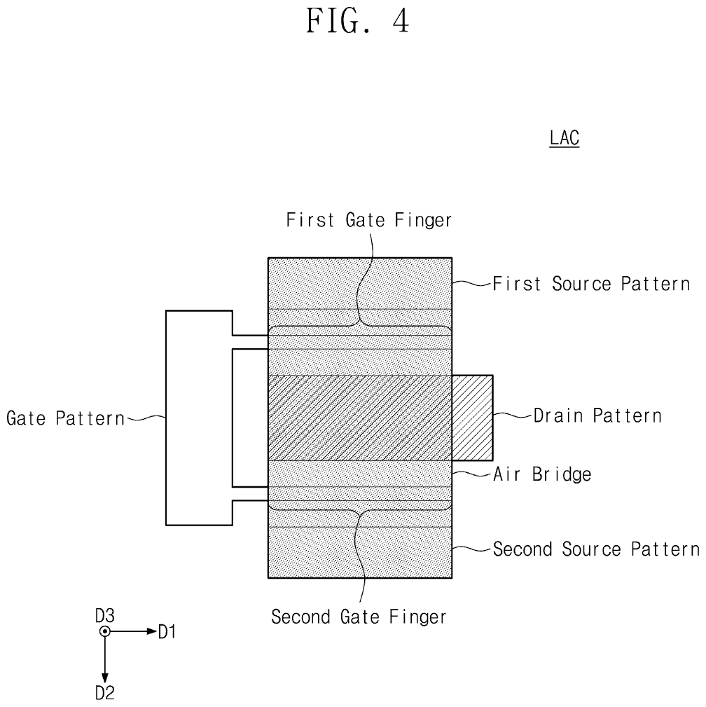

FIG. 4 is a view illustrating the general low noise amplification circuit LAC. Referring to FIG. 4, a process drawing of the general low noise amplification circuit LAC as viewed in the third direction D3 is illustrated. The air bridge may overlap a portion of the first gate finger and a portion of the second gate finger in the third direction D3. The overlapping portions may function as a parasitic capacitor. The parasitic capacitor may increase communication noise.

FIG. 5 is a view illustrating the general low noise amplification circuit LAC. Referring to FIG. 5, a process drawing of the general low noise amplification circuit LAC as viewed in the first direction D1 is illustrated.

The general low noise amplification circuit LAC may have a first gate-source capacitor Cgs1 by the air bridge and the first gate finger, a second gate-source capacitor Cgs2 by the air bridge and the second gate finger, and a gate-drain capacitor Cds by the air bridge and the drain pattern.

The gate-source capacitor Cgs of the low noise amplification circuit may affect the signal-to-noise ratio (SNR) and the noise factor of the low noise amplification circuit.

The gate-source capacitor Cgs of the low noise amplification circuit may contribute to a noise components as a parasitic component. Accordingly, when the gate-source capacitor Cgs decreases, the noise component may decrease, and thus the SNR may be improved.

$$\text{?} \qquad [ Equation 1 ]$$

$$\text{?} \text{indicates text missing or illegible when filed}$$

According to Equation 1, an influence of the gate-source capacitor Cgs on the noise factor is described. F may mean the noise factor of the low noise amplification circuit. The noise factor may represent the signal characteristics of the general low noise amplification circuit LAC. Q may mean the quality factor of the low noise amplification circuit. IRs may correspond to the mean square of the current of the input signal IS. Inout may correspond to the mean square of the current of the output signal OS.

When the gate-source capacitor Cgs decreases, the quality factor of the low noise amplification circuit may increase. When the quality factor of the low noise amplification circuit increases, the noise factor decreases. The decrease in the noise factor means that the noise ratio of a signal passing through the low noise amplification circuit decreases. When the gate-source capacitor Cgs of the low noise amplification circuit decreases, the noise factor of the low noise amplification circuit may be improved.

The gate-source capacitor Cgs may affect the amplification gain of the low noise amplification circuit. According to Equation 2 below, an influence of the gate-source capacitor Cgs on the amplification gain is described.

$$\text{?} \qquad [ Equation 2 ]$$

$$\text{?} \text{indicates text missing or illegible when filed}$$

According to Equation 2, when the gate-source capacitor Cgs decreases, the cutoff frequency of the general low noise amplification circuit LAC may increase. As the cutoff frequency of the transistors used in the low noise amplification circuit increases, the amplification gain of the low noise amplification circuit may increase. Accordingly, a design that decreases the gate-source capacitor Cgs may be required to increase the amplification gain of the low noise amplification circuit.

The air bridge of the general low noise amplification circuit LAC may overlap a portion of the first gate finger and a portion of the second gate finger in the third direction D3. The overlapping portions may function as the gate-source capacitor Cgs.

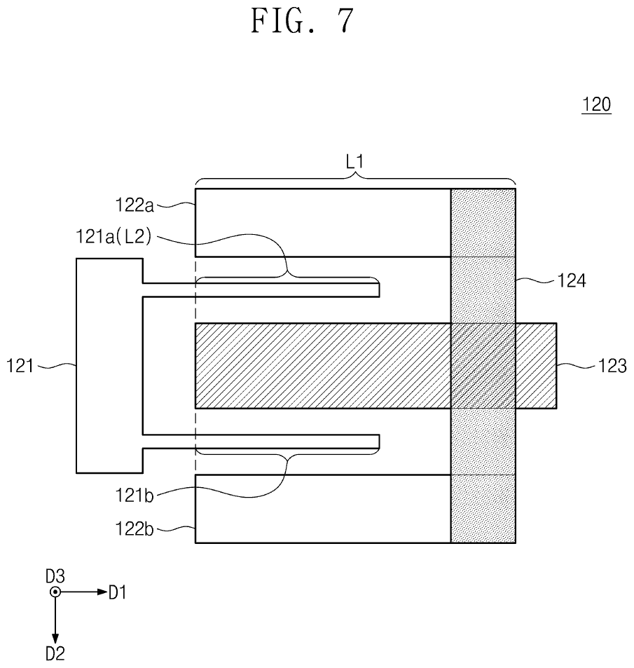

FIG. 6 is a view illustrating a low noise amplification circuit according to some embodiments of the present disclosure. FIG. 7 is a view illustrating the low noise amplification circuit according to some embodiments of the present disclosure. Referring to FIGS. 6 and 7, a process drawing of the low noise amplification circuit 120 is illustrated.

The low noise amplification circuit 120 may include a first source pattern 122a, a second source pattern 122b, a gate pattern 121, a drain pattern 123, and an air bridge 124.

The first source pattern 122a, the gate pattern 121, and the drain pattern 123 may correspond to the first transistor M1 of FIG. 1. The second source pattern 122b, the gate pattern 121, and the drain pattern 123 may correspond to the second transistor M2 of FIG. 1.

Specifically, the first source pattern 122a may correspond to the first node N1 of FIG. 1. The second source pattern 122b may correspond to the second node N2 of FIG. 1. The gate pattern 121 may correspond to the input node Ni of FIG. 1. The drain pattern 123 may correspond to the output node No of FIG. 1.

The first source pattern 122a may extend in the first direction D1. The first source pattern 122a may have a first length in the first direction D1.

The gate pattern 121 may include a first gate finger 121a, a second gate finger 121b, and a gate body.

The first gate finger 121a may be located between the first source pattern 122a and the drain pattern 123 in the second direction D2. The first gate finger 121a may be included in the first source pattern 122a in the second direction D2 and may be spaced apart from the air bridge 124 in the first direction D1. In other words, unlike the general first gate finger of FIG. 3, the first gate finger 121a may not overlap the air bridge 124 in the third direction D3. The first gate finger 121a may have a second length shorter than the first length in the first direction D1.

The second gate finger 121b may be located between the drain pattern 123 and the second source pattern 122b in the second direction D2 and may be included in the second source pattern 122b in the second direction D2. The second gate finger 121b may be spaced apart from the air bridge 124 in the first direction D1. In other words, unlike the general second gate finger of FIG. 3, the second gate finger 121b may not overlap the air bridge 124 in the third direction D3. The second gate finger 121b may have the second length in the first direction D1.

The gate body may refer to a portion of the gate pattern excluding the first and second gate fingers.

The drain pattern 123 may be spaced apart from the first gate finger 121a in the second direction D2. The drain pattern 123 may generate the output signal OS.

The second source pattern 122b may be spaced apart from the second gate finger 121b in the second direction D2. The second source pattern 122b may have the first length in the first direction D1.

The air bridge 124 may make contact with a portion of the first source pattern 122a and a portion of the second source pattern 122b in the third direction D3. The air bridge 124 may be spaced apart from the first gate finger 121a and the second gate finger 121b in the first direction D1.

The air bridge 124 may not overlap the gate fingers 121a and 121b of the gate pattern 121 in the third direction D3. The air bridge 124 may short-circuit the source patterns 122a and 122b while bypassing the gate fingers 121a and 121b.

According to embodiments of the present disclosure, a parasitic capacitor between the gate fingers 121a and 121b and the air bridge 124 may be decreased because the air bridge 124 has a physical structure bypassing the gate fingers 121a and 121b. For example, in the general low noise amplification circuit LAC of FIG. 3, a parasitic capacitor may be formed between the air bridge and the gate fingers. In contract, since the air bridge 124 of the present disclosure bypasses the gate fingers 121a and 121b, a parasitic capacitor may not be formed between the air bridge 124 and the gate fingers 121a and 121b in the third direction D3.

The air bridge 124 may short-circuit the source patterns 122a and 122b. Accordingly, when the parasitic capacitor between the air bridge 124 and the gate fingers 121a and 121b decreases, the gate-source capacitor Cgs of the low noise amplification circuit 120 may decrease. When the gate-source capacitor Cgs decreases, the SNR and noise factor of the low noise amplification circuit 120 may be improved, and the amplification gain of the low noise amplification circuit 120 may increase.

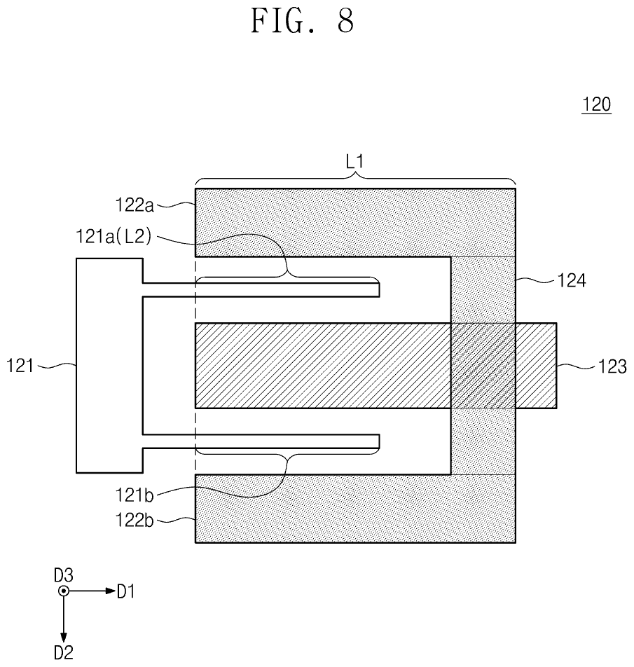

FIG. 8 is a view illustrating the low noise amplification circuit 120 according to some embodiments of the present disclosure. Referring to FIG. 8, a process drawing of the low noise amplification circuit 120 as viewed in the third direction D3 is illustrated.

An air bridge 124 of the low noise amplification circuit 120 according to some embodiments of the present disclosure may overlap the entirety of source patterns 122a and 122b. When the air bridge 124 overlaps the entirety of the source patterns 122a and 122b, this means that the air bridge 124 extends in the first direction D1 along the first source pattern 122a, connects one end of the first source pattern 122a that faces in the first direction D1 and one end of the second source pattern 122b that faces in the first direction D1, and extends in the first direction DI along the second source pattern 122b.

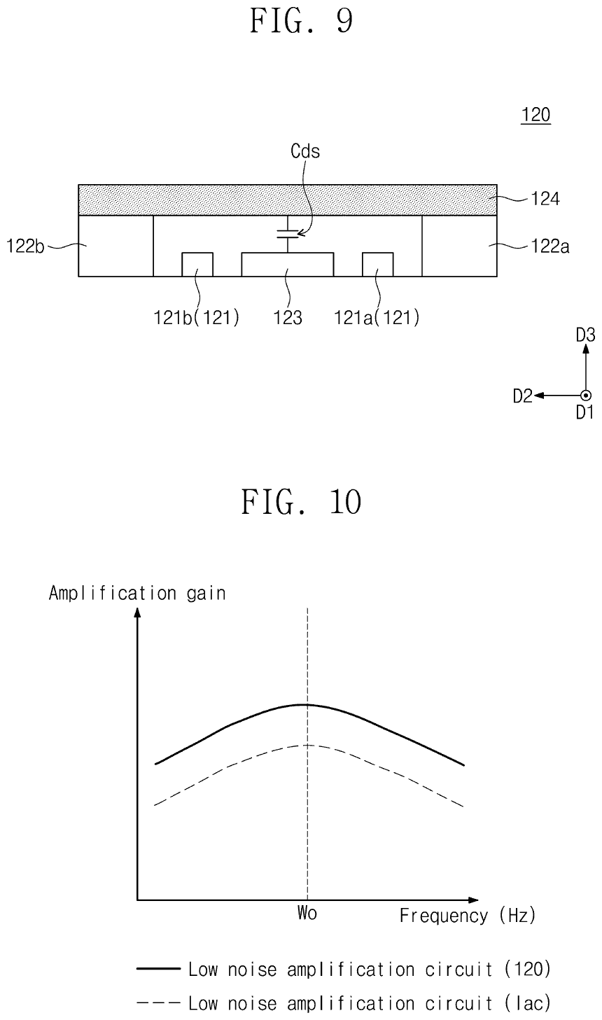

FIG. 9 is a view illustrating the low noise amplification circuit according to some embodiments of the present disclosure. Referring to FIG. 9, a process drawing of the low noise amplification circuit 120 as viewed in the first direction D1 is illustrated.

The low noise amplification circuit 120 according to an embodiment of the present disclosure may include the gate pattern 121, the first source pattern 122a, the second source pattern 122b, the drain pattern 123, and the air bridge 124.

The air bridge 124 may overlap the drain pattern 123 in the third direction D3. A gate-drain capacitor Cds may be formed as a parasitic capacitor between the air bridge 124 and the drain pattern 123.

The air bridge 124 may not overlap the first gate finger 121a and the second gate finger 121b of the gate pattern 121 in the third direction D3. A parasitic capacitor may not be formed between the air bridge 124 and the first gate finger 121a. A parasitic capacitor may not be formed between the air bridge 124 and the second gate finger 121b. Since a gate-source capacitor that is a parasitic capacitor is omitted unlike in the general low noise amplification circuit LAC of FIG. 5, the SNR and noise factor of the low noise amplification circuit 120 may be improved.

FIG. 10 is a graph depicting an improvement in the amplification gain of the low noise amplification circuit 120 according to some embodiments of the present disclosure. Referring to FIG. 10, the amplification gain of the low noise amplification circuit 120 according to embodiments of the present disclosure and the amplification gain of the general low noise amplification circuit LAC will be described.

The low noise amplification circuit 120 may correspond to the low noise amplification circuit 120 of FIG. 6. The general low noise amplification circuit LAC may correspond to the general low noise amplification circuit LAC of FIG. 3. In the graph, the horizontal axis represents frequency, and the vertical axis represents amplification gain. A resonant frequency Wo may refer to a frequency at which the magnitude of the amplification gain is maximized.

Since the low noise amplification circuit 120 of the present disclosure is designed such that the air bridge bypasses the gate fingers, the SNR may be improved. Referring to the waveforms of the low noise amplification circuit 120 and the general low noise amplification circuit LAC, the amplification gain of the low noise amplification circuit 120 may be higher than the amplification gain of the general low noise amplification circuit LAC.

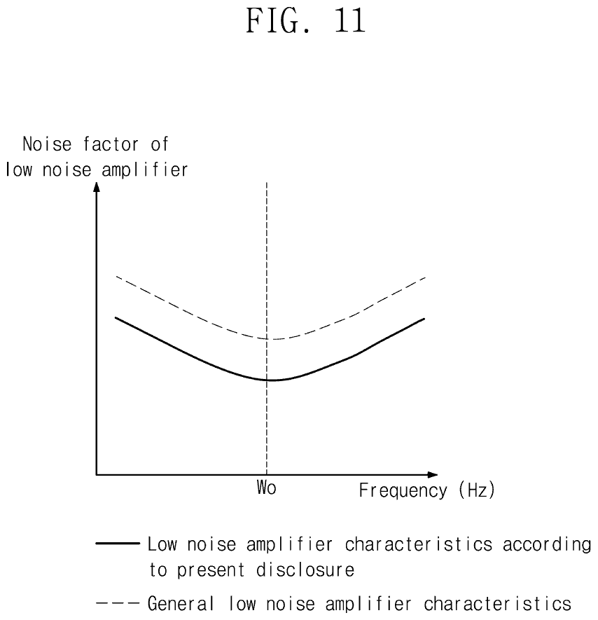

FIG. 11 is a graph depicting an improvement in the noise factor of the low noise amplifier according to some embodiments of the present disclosure. Referring to FIG. 11, the noise factor of the low noise amplification circuit 120 according to embodiments of the present disclosure and the noise factor of the general low noise amplification circuit LAC will be described.

The low noise amplification circuit 120 may correspond to the low noise amplification circuit 120 of FIG. 6. The general low noise amplification circuit LAC may correspond to the general low noise amplification circuit LAC of FIG. 3. In the graph, the horizontal axis represents frequency, and the vertical axis represents low noise amplifier noise factor. The resonant frequency Wo may refer to the frequency at which the magnitude of the amplification gain is maximized.

Since the low noise amplification circuit 120 of the present disclosure is designed such that the air bridge bypasses the gate fingers, the noise factor may be improved. Referring to the waveforms of the low noise amplification circuit 120 and the general low noise amplification circuit LAC, the noise factor of the low noise amplification circuit 120 may be smaller than the noise factor of the general low noise amplification circuit LAC.

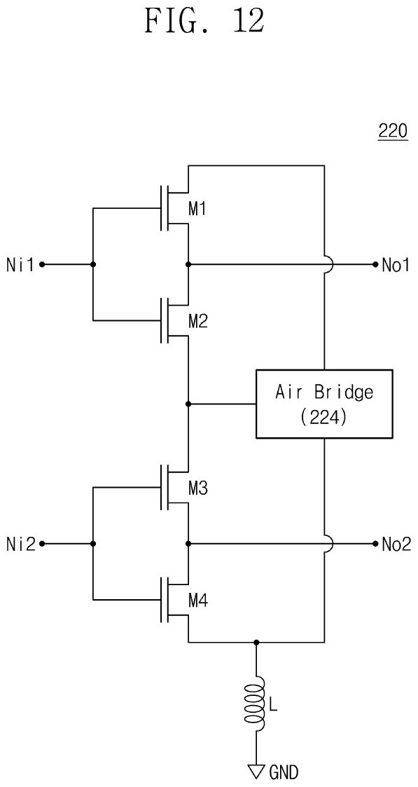

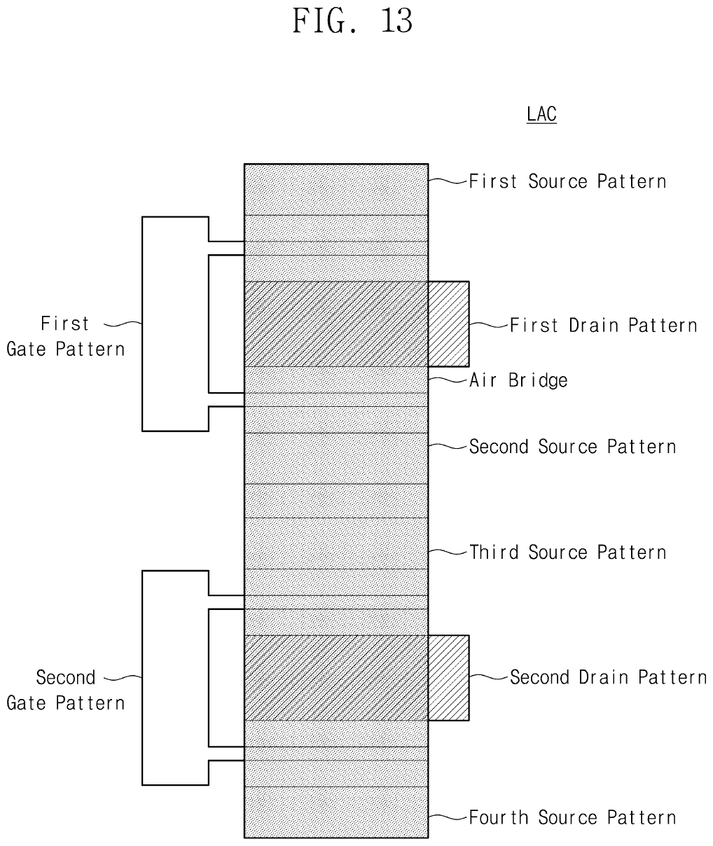

FIG. 12 is a circuit diagram illustrating a low noise amplification circuit having more than two source patterns according to some embodiments of the present disclosure. Referring to FIG. 12, the low noise amplification circuit 220 may include first to fourth transistors M1 to M4 connected in series, an air bridge 224, and an inductor L. For a better understanding of the present disclosure, the low noise amplification circuit 220 is illustrated as including four transistors M1 to M4. However, the present disclosure is not limited thereto, and the low noise amplification circuit 220 may include more or less than four transistors.

The low noise amplification circuit 220 may be connected with a first input node Ni1, a second input node Ni2, a first output node No1, and a second output node No2. The first and second input nodes Ni1 and Ni2 may be connected with the first matching circuit 110 of FIG. 1. The first and second output nodes No1 and No2 may be connected with the second matching circuit 130 of FIG. 1.

The first and second input nodes Ni1 and Ni2 may receive first and second input signals, respectively. The first and second input signals may be the same signal or may refer to signals in different communication bands. The first and second output nodes No1 and No2 may generate first and second output signals, respectively. The first and second output signals may correspond to the first and second input signals, respectively.

The first and second transistors M1 and M2 may operate in response to the first input signal received through the first input node Ni1. The gate patterns of the first and second transistors M1 and M2 may be connected to the first input node Ni1. The drain patterns of the first and second transistors M1 and M2 may be connected to the first output node No1. The source patterns of the first and second transistors M1 and M2 may be connected to the air bridge 224.

The third and fourth transistors M3 and M4 may operate in response to the second input signal received through the second input node Ni2. The gate patterns of the third and fourth transistors M3 and M4 may be connected to the second input node Ni2. The drain patterns of the third and fourth transistors M3 and M4 may be connected to the second output node No2. The source patterns of the third and fourth transistors M3 and M4 may be connected to the air bridge 224.

The air bridge 224 may be connected with the source patterns of the first to fourth transistors M1 to M4 and the inductor L.

FIG. 13 is a view illustrating a general low noise amplification circuit having more than two source patterns. Referring to FIG. 13, a process drawing of the general low noise amplification circuit is illustrated in the third direction D3.

The general low noise amplification circuit may include first and second gate patterns, first to fourth source patterns, first and second drain patterns, and an air bridge. The first gate pattern may include a first gate body, a first gate finger, and a second gate finger. The second gate pattern may include a second gate body, a third gate finger, and a fourth gate finger.

Referring to FIGS. 12 and 13, the first source pattern, the first gate finger, and the first drain pattern may correspond to the first transistor M1. The second source pattern, the second gate finger, and the first drain pattern may correspond to the second transistor M2. The third source pattern, the third gate finger, and the second drain pattern may correspond to the third transistor M3. The fourth source pattern, the fourth gate finger, and the second drain pattern may correspond to the fourth transistor M4.

The first gate pattern may be connected to the first input node Ni1. The second gate pattern may be connected to the second input node Ni2. The first drain pattern may be connected to the first output node No1. The second drain pattern may be connected to the second output node No2.

The air bridge may make contact with the first to fourth source patterns in the third direction D3. The air bridge may overlap the first to fourth gate fingers in the third direction D3. The overlapping portions may function as a parasitic capacitor. The parasitic capacitor may increase communication noise. The air bridge may short-circuit the first to fourth source patterns, and therefore the parasitic capacitor between the air bridge and the gate fingers may contribute to an increase in the gate-source capacitor Cgs of the transistor.

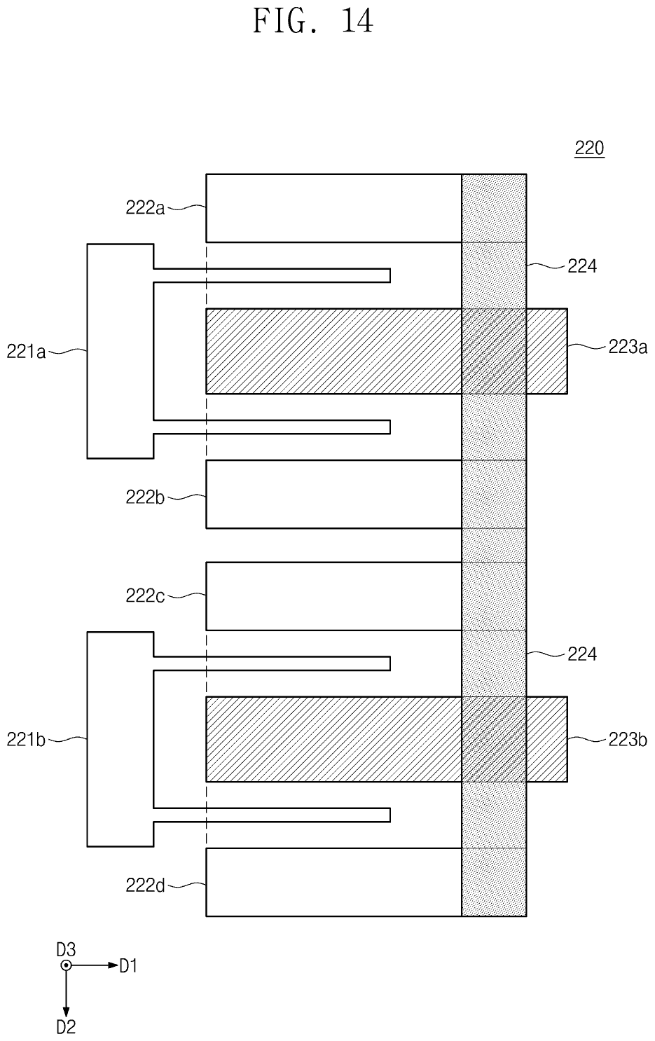

FIG. 14 is a view illustrating the low noise amplification circuit 220 having more than two source patterns according to some embodiments of the present disclosure.

Referring to FIG. 14, a process drawing of the low noise amplification circuit 220 is illustrated in the third direction D3. The low noise amplification circuit 220 may include first and second gate patterns 221a and 221b, first to fourth source patterns 222a to 222d, first and second drain patterns 223a and 223b, and the air bridge 224. The first gate pattern 221a may include a first gate body, a first gate finger, and a second gate finger. The second gate pattern 221b may include a second gate body, a third gate finger, and a fourth gate finger.

Referring to FIGS. 12 and 14, the first source pattern 222a, the first gate finger, and the first drain pattern 223a may correspond to the first transistor M1. The second source pattern 222b, the second gate finger, and the first drain pattern 223a may correspond to the second transistor M2. The third source pattern 222c, the third gate finger, and the second drain pattern 223b may correspond to the third transistor M3. The fourth source pattern 222d, the fourth gate finger, and the second drain pattern 223b may correspond to the fourth transistor M4.

The first gate pattern 221a may be connected to the first input node Ni1. The second gate pattern 221b may be connected to the second input node Ni2. The first drain pattern 223a may be connected to the first output node No1. The second drain pattern 223b may be connected to the second output node No2.

The air bridge 224 may be connected with the first to fourth source patterns in the third direction D3. The air bridge 224 may be spaced apart from the first to fourth gate fingers in the first direction D1. In other words, since the air bridge 224 bypasses the gate fingers, a parasitic capacitor may not be formed between the air bridge 224 and the gate fingers in the third direction D3.

The air bridge 224 may short-circuit the first to fourth source patterns 222a to 222d. Accordingly, when a parasitic capacitor between the air bridge 224 and the gate fingers decreases, the gate-source capacitor Cgs of the low noise amplification circuit 220 may decrease. When the gate-source capacitor Cgs decreases, the SNR and noise factor of the low noise amplification circuit 220 may be improved, and the amplification gain of the low noise amplification circuit 220 may increase.

According to the embodiments of the present disclosure, the low noise amplifier including the air bridge is provided.

The size of the low noise amplifier may be reduced by sharing the inductive elements by the transistors short-circuited by the air bridge instead of connecting the inductive elements to the transistors of the low noise amplifier. In addition, the signal-to-noise ratio (SNR) and noise factor of the RF signal may be improved by reducing the parasitic capacitor by designing the air bridge to bypass the gate pattern.

While the present disclosure has been described with reference to embodiments thereof, it will be apparent to those of ordinary skill in the art that various changes and modifications may be made thereto without departing from the spirit and scope of the present disclosure as set forth in the following claims.

1. A low noise amplifier comprising:
a first matching circuit configured to generate an input signal, based on an input radio frequency signal;
a low noise amplification circuit configured to generate an output signal, based on the input signal; and
a second matching circuit configured to radiate an output radio frequency signal, based on the output signal,
wherein the low noise amplification circuit includes:
a first source pattern configured to extend in a first direction, the first source pattern having a first length in the first direction;
a first gate finger configured to receive the input signal and spaced apart from the first source pattern in a second direction perpendicular to the first direction, the first gate finger having a second length shorter than the first length in the first direction;
a drain pattern configured to generate the output signal and spaced apart from the first gate finger in the second direction;
a second gate finger configured to receive the input signal and spaced apart from the drain pattern in the second direction, the second gate finger having the second length in the first direction;
a second source pattern spaced apart from the second gate finger in the second direction, the second source pattern having the first length in the first direction; and
an air bridge contacting with the first and second source patterns in a third direction perpendicular to a plane defined by the first and second directions, the air bridge being spaced apart from the first and second gate fingers in the first direction.

2. The low noise amplifier of claim 1, wherein the low noise amplification circuit further includes an inductor connected between the air bridge and a ground node.

3. The low noise amplifier of claim 1, wherein the air bridge further includes:
a first portion contacting with the first source pattern in the third direction, being spaced apart from the first gate finger in the second direction, and extending in the first direction;
a second portion contacting with the second source pattern in the third direction, being spaced apart from the second gate finger in the second direction, and extending in the first direction; and
a third portion connecting the first portion and the second portion, being spaced apart from the first gate finger and the second gate finger, and extending in the second direction.

4. The low noise amplifier of claim 1, wherein the air bridge is made of metal.

5. The low noise amplifier of claim 1, wherein the first matching circuit is configured to perform an impedance matching of the input radio frequency signal, and
wherein the second matching circuit is configured to perform an impedance matching of the output signal.

6. The low noise amplifier of claim 1, wherein the low noise amplification circuit further includes a gate pattern,
wherein the gate pattern includes a gate body, the first gate finger, and the second gate finger, and
wherein the gate body is configured to receive the input signal and provide the input signal to the first gate finger and the second gate finger.

7. The low noise amplifier of claim 1, wherein the drain pattern is a first drain pattern,
wherein the low noise amplification further includes:
a third source pattern spaced apart from the second source pattern in the second direction, the third source pattern having the first length in the first direction;
a third gate finger configured to receive the input signal and spaced apart from the third source pattern in the second direction, the third gate finger having the second length in the first direction;
a second drain pattern configured to generate the output signal and spaced apart from the third gate finger in the second direction;
a fourth gate finger configured to receive the input signal and spaced apart from the second drain pattern in the second direction, the fourth gate finger having the second length in the first direction; and
a fourth source pattern spaced apart from the fourth gate finger in the second direction, the fourth source pattern having the first length in the first direction, and
wherein the air bridge contacts with the first to fourth source patterns in the third direction and is spaced apart from the first to fourth gate fingers in the first direction.

8. The low noise amplifier of claim 7, wherein the input signal includes a first input signal and a second input signal of different communication band from the first input signal,
wherein the first gate finger and the second gate finger are configured to receive the first input signal,
wherein the third gate finger and the fourth gate finger are configured to receive the second input signal,
wherein the output signal includes a first output signal corresponding to the first input signal and a second output signal corresponding to the second output signal,
wherein the first drain pattern is configured to generate the first output signal, and
wherein the second drain pattern is configured to generate the second output signal.

9. A low noise amplification circuit comprising:
a first transistor;
a second transistor; and
an air bridge,
wherein the first transistor includes:
a first source pattern configured to extend in a first direction, the first source pattern having a first length in the first direction;
a first gate finger connected to an input node and spaced apart from the first source pattern in a second direction perpendicular to the first direction, the first gate finger having a second length shorter than the first length in the first direction; and
a first drain pattern connected to an output node and spaced apart from the first gate finger in the second direction,
wherein the second transistor includes:
a second drain pattern connected to the output node;
a second gate finger connected to the input node and spaced apart from the second drain pattern in the second direction, the second gate finger having the second length in the first direction; and
a second source pattern spaced apart from the second gate finger in the second direction, the second source pattern having the first length in the first direction, and
wherein the air bridge contacts with the first and second source patterns in a third direction perpendicular to a plane defined by the first and second directions, the air bridge being spaced apart from the first and second gate fingers in the first direction.

10. A method of operating a low noise amplifier, the method comprising:
generating an input signal based on the input radio frequency signal;
generating, by a low noise amplification circuit of the low noise amplifier, an output signal based on the input signal; and
radiating an output radio frequency signal based on the output signal,
wherein the low noise amplification circuit includes:
a first source pattern configured to extend in a first direction, the first source pattern having a first length in the first direction;
a first gate finger configured to receive the input signal and spaced apart from the first source pattern in a second direction perpendicular to the first direction, the first gate finger having a second length shorter than the first length in the first direction;
a drain pattern configured to generate the output signal and spaced apart from the first gate finger in the second direction;
a second gate finger configured to receive the input signal and spaced apart from the drain pattern in the second direction, the second gate finger having the second length in the first direction;
a second source pattern spaced apart from the second gate finger in the second direction, the second source pattern having the first length in the first direction; and
an air bridge configured to make contacting with the first and second source patterns in a third direction perpendicular to a plane defined by the first and second directions, the air bridge being spaced apart from the first and second gate fingers in the first direction.
